(19) United States
(12) Patent Application Publication
(10) Pub. No.: US 2010/0266968 A1
(43) Pub. Date: Oct. 21, 2010

(54) EXPOSURE APPARATUS, DEVICE MANUFACTURING SYSTEM, AND METHOD OF MANUFACTURING DEVICE

(75) Inventor: Yukio Nakano, Utsunomiya-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/760,957

(22) Filed: Apr. 15, 2010

(30) Foreign Application Priority Data
Apr. 21, 2009 (JP) 2009-103359

(51) Int. Cl. G03F 7/20; G03B 27/42

(52) U.S. Cl. 430/325; 355/53

(57) ABSTRACT

An exposure apparatus comprises an exposure device configured to perform an exposure process for a substrate, and a controller configured to control an operation of the exposure device in accordance with control software and perform an update process for the control software. The controller is configured to queue an exposure job corresponding to the exposure process and an update job corresponding to the update process; and cause the exposure device to perform an exposure process corresponding to the queued exposure job if the queued exposure job is output, and perform an update process corresponding to the queued update job if the queued update job is output.

### BACKGROUND OF THE INVENTION

1. Field of the Invention

The present invention relates to an exposure apparatus serving as an apparatus for manufacturing a device such as a semiconductor device or a liquid crystal panel, a device manufacturing system including the exposure apparatus, and a method of manufacturing a device using the exposure apparatus.

2. Description of the Related Art

The performance and function of apparatuses for manufacturing various kinds of products have improved to keep up with improvements in performance and function of these various kinds of products. The performance and function of exposure apparatuses serving as apparatuses for manufacturing semiconductor devices such as an integrated circuit and a large-scale integration and a liquid crystal panel have also improved to keep up with advance in micropatterning and an increase in packing density of these devices. Exposure apparatuses called a stepper and a scanner are commonly used for this manufacture. These apparatuses sequentially transfer a pattern formed on an original (e.g., a reticle) to a plurality of regions on a substrate (e.g., a wafer) while performing step movement of the substrate. An apparatus that performs transfer to one region by full-field exposure is called a stepper, whereas one that performs transfer to one region while scanning the region using a slit is called a scanner.

An exposure apparatus including two substrate stages which hold substrates has recently been put into practical use to meet two demands for improvements in both the overlay accuracy and throughput which are of prime importance for exposure apparatuses. In addition, the development of an exposure apparatus which attains high-resolution transfer by filling the space between a substrate and a projection optical system which projects an image of an original with a liquid has also progressed.

Amid such improvements in accuracy and performance of exposure apparatuses, software for controlling an exposure apparatus is upgraded as needed so that it becomes more accurate and sophisticated as well. Such software upgrading is often applicable not only to an exposure apparatus to be newly developed but also to an exposure apparatus that has already been put into operation. Hence, upgrading (version upgrading) of software on an active exposure apparatus is frequently performed.

One example of a method of updating control software on an exposure apparatus in the prior art will be described herein. FIG. 10 is a flowchart illustrating one example of the procedure for updating control software on an exposure apparatus by the user.

First, the user inspects the hardware configuration and functions to be added and upgraded of an exposure apparatus, and determines the version of control software to be updated to (S1001). Next, the user acquires the updated version of the control software (S1002). An updated version of the control software is typically provided in the form of software stored in a medium such as an optical/magnetic disk by the manufacturing vendor of the exposure apparatus. The user determines the period for which the control software on the exposure apparatus is updated (S1003). Updating of control software on an exposure apparatus typically requires stop of the control software (i.e., stop of an exposure process) and supervision of the operator (and additionally, the manufacturing vendor of the exposure apparatus), so the user determines the update period by taking account of the production plan/manning plan adopted.

When the planned update period has come, the user ends the exposure process of the exposure apparatus (S1004), and updates the control software (S1005). After the updating is completed, the user conducts an operation test of the exposure apparatus and examines the test result (S1006). If the user determines based on the test result that the updating has succeeded, he or she resumes the exposure process of the exposure apparatus (S1007). With the foregoing processing, a series of steps of the update procedure is completed.

Further, a semiconductor device manufacturing plant will be briefly explained as one example of the location where products are manufactured using an exposure apparatus. FIG. 11 is a block diagram illustrating one example of the configuration of a semiconductor manufacturing system that includes an exposure apparatus and is installed in a semiconductor device manufacturing plant.

The semiconductor device manufacturing plant is equipped with a communication network 1101 such as a local area network, and one or more exposure apparatuses 1102 and a control apparatus 1103 which controls the manufacturing process are connected to each other via the communication network 1101. The control apparatus 1103 remotely controls the exposure apparatus 1102. In addition, the semiconductor device manufacturing plant is generally equipped with various types of manufacturing apparatuses 1104 associated with the manufacture of semiconductor devices. The various types of manufacturing apparatuses 1104 can be, for example, a deposition apparatus, development apparatus, cleaning apparatus, inspection apparatus, and measurement apparatus. The manufacturing apparatuses 1104 are typically connected to the control apparatus 1103 via the communication network 1101 and remotely controlled by the control apparatus 1103, like the exposure apparatus 1102.

The procedure for updating the control software in the semiconductor manufacturing system shown in FIG. 11 will be exemplified. In step S1004 of FIG. 10, the control apparatus 1103 stops requesting the exposure apparatus 1102 for an exposure process. In step S1007 of FIG. 10, the control apparatus 1103 starts requesting the exposure apparatus 1102 for an exposure process. In step S1005 of FIG. 10, the user updates the control software on the exposure apparatus 1102 by an operation of, for example, inserting a medium which stores an updated version of the control software into the exposure apparatus 1102 and copying the updated version of the control software into a storage included in the exposure apparatus 1102 (see Japanese Patent Laid-Open No. 11-296352).

As has been described above, updating of control software on an exposure apparatus requires stop of an exposure process at least temporarily. Under the circumstance, one proposed update method shortens as much as possible the period for which an exposure process is stopped. Japanese Patent Laid-Open No. 11-282655, for example, proposes a method of updating control software on an exposure apparatus while the control software is in operation. In this proposal, the control software on the exposure apparatus 1102 is updated by replacing the control software before updating in the storage of the exposure apparatus 1102 with an updated version, loading the updated version to an address on the memory, other than that of the control software before updating in execution, and switching the execution start address to the new address.

As described previously, updating of control software is an effective method that allows function addition and modification even in an active exposure apparatus.

Since an exposure apparatus is a production facility for manufacturing products, it is generally used without interruption all day. Hence, the downtime for which an exposure apparatus is used for purposes other than an exposure process, such as maintenance, adversely affects the user productivity. Since the above-mentioned updating of control software requires stop of an exposure process at least temporarily, this again adversely affects the productivity to a considerable extent. Furthermore, the updating requires update period determination and supervision of the operator and vendor of the exposure apparatus. The stop of the exposure apparatus also adversely affects production in other semiconductor manufacturing apparatuses. More specifically, an apparatus which coats a wafer with a photosensitive agent (resist) before exposure by the exposure apparatus needs to interlock with the exposure apparatus to process the wafer. This is because the exposure process must be ended within a predetermined time after the wafer is coated with a photosensitive agent.

Stop of the exposure apparatus or updating of the control software is desirably performed within the time for which products whose production time has a margin on the plan are produced in accordance with the production plan of semiconductor device products being manufactured. Also, the control software needs to be updated ahead of production of products that require function addition and modification by the updating. Moreover, an operation test of the exposure apparatus, which accompanies updating of the control software, desirably interlocks with the updating.

### SUMMARY OF THE INVENTION

The present invention provides, for example, an exposure apparatus advantageous in respect of updating of control software thereof.

According to the present invention, there is provided an exposure apparatus comprising: an exposure device configured to perform an exposure process for a substrate; and a controller configured to control an operation of the exposure device in accordance with control software and perform an update process for the control software, wherein the controller is configured to queue an exposure job corresponding to the exposure process and an update job corresponding to the update process; and causes the exposure device to perform an exposure process corresponding to the queued exposure job if the queued exposure job is output, and perform an update process corresponding to the queued update job if the queued update job is output.

Further features of the present invention will become apparent from the following description of exemplary embodiments with reference to the attached drawings.

### BRIEF DESCRIPTION OF THE DRAWINGS

FIG. 1 is a flowchart showing a method of updating control software on an exposure apparatus in the first embodiment;

FIG. 2 is a block diagram showing the configuration of a semiconductor manufacturing system according to the present invention;

FIG. 3 is a block diagram illustrating an example of the configuration of an exposure apparatus according to the present invention;

FIG. 4 is a view showing the arrangement of an exposure device according to the present invention;

FIG. 5 is a block diagram illustrating an example of the configuration of a control apparatus according to the present invention;

FIG. 6 is a block diagram illustrating an example of the configuration of a storage apparatus according to the present invention;

FIGS. 7A and 7B are flowcharts showing a method of updating control software on an exposure apparatus in the second embodiment;

FIG. 8 is a block diagram showing the configuration of a system that updates the control software in the second embodiment;

FIG. 9 is a view illustrating an example of display on a window for job scheduling in the control apparatus according to the present invention;

FIG. 10 is a flowchart showing a method of updating control software on an exposure apparatus in the prior art; and

FIG. 11 is a block diagram showing the configuration of a semiconductor manufacturing system in the prior art.

### DESCRIPTION OF THE EMBODIMENTS

### First Embodiment

The first embodiment of an exposure apparatus and device manufacturing system to which the present invention is applied will be described below.

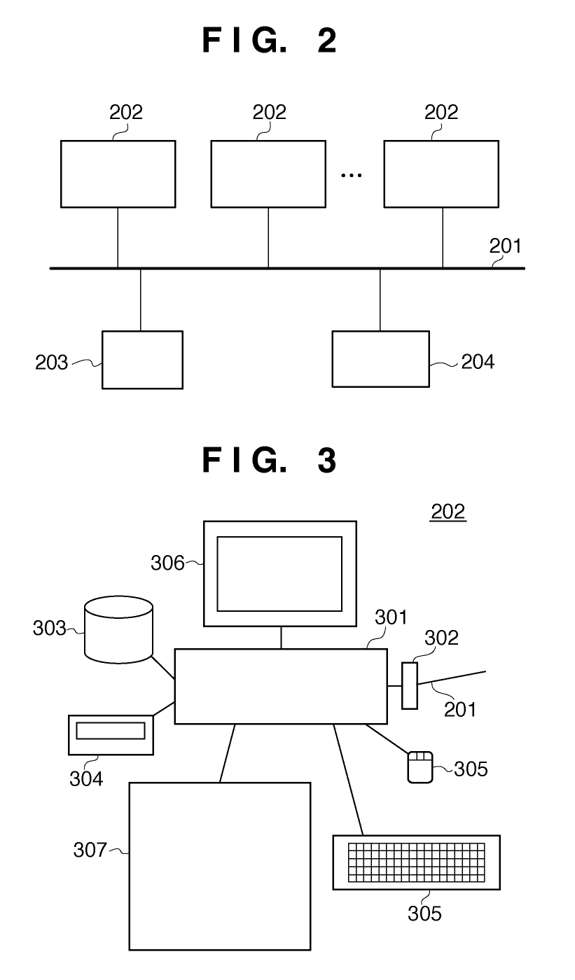

FIG. 2 is a block diagram showing the configuration of a system that updates control software on an exposure apparatus to which the present invention is applied. The system shown in FIG. 2 is typically installed in a semiconductor device manufacturing plant serving as the manufacturing location of semiconductor devices.

One or more exposure apparatuses 202 each implement a part of the device manufacturing process by exposing a substrate (wafer) via a circuit designed on an original (reticle). Details of the exposure apparatus 202 will be described later. A control apparatus 203 controls the manufacturing process and remotely controls the exposure apparatus 202. Details of the control apparatus 203 will be described later. The exposure apparatus 202 and control apparatus 203 are connected to each other via a communication network 201 such as a local area network. Although not shown for the sake of drawing simplicity, the semiconductor device manufacturing plant is also typically equipped with various types of manufacturing apparatuses, associated with the device manufacturing process, such as a deposition apparatus, development apparatus, cleaning apparatus, inspection apparatus, and measurement apparatus. These manufacturing apparatuses are also generally connected to the control apparatus 203 via the communication network 201.

A wafer serving as a component of a semiconductor device is processed upon transferring among the exposure apparatus 202 and other manufacturing apparatuses based on the defined manufacturing process. The manufacturing process is set in the control apparatus 203. That is, a process command including detailed information of a process to be performed for one lot of wafers (one unit including a plurality of wafers to be processed under the same conditions) is generated and inserted into the exposure apparatus 202 and other manufacturing apparatuses via the communication network 201. The process command will be referred to as a job hereinafter. A job inserted into the exposure apparatus generally includes pieces of information concerning a reticle used and various types of parameter conditions for exposure of a wafer lot. A job concerning an exposure process, which is inserted into the exposure apparatus, will be referred to as an exposure job hereinafter.

Reference numeral 204 denotes a storage apparatus that stores information necessary for an update process for the control software on the exposure apparatus. The storage apparatus 204 stores update software information and an update image that are necessary to update the control software. Details of the update software information will be described later. The update image includes at least an update file to be updated to by an update process, and an update file installer program. The storage apparatus can provide the update software information and the update image via the communication network 201 to update the control software on the exposure apparatus. Details of the storage apparatus that stores the update software information will be described later.

Details of the exposure apparatus 202 will be described next. FIG. 3 is a block diagram illustrating an example of the configuration of the exposure apparatus 202. The exposure apparatus 202 includes a controller 301, a communication device 302, a storage 303, a media reading unit 304, one or more operation units 305, a display 306, and an exposure device 307. As an example, the controller 301 can be implemented by a known computer or board computer, and the communication device 302 can be implemented by a known communication board compatible with the communication network 201. Also, as an example, the storage 303 can be implemented by a known hard disk, the media reading unit 304 can be implemented by a known reading device for an optical/magnetic disk or a magnetic tape, the operation units 305 can be implemented by a known keyboard and mouse, and the display 306 can be implemented by a known display.

The exposure device 307 includes a mechanism capable of exposure based on an instruction from the controller 301. Details of the exposure device 307 will be described later. The controller 301 can control the exposure device 307 by operating the control software stored in the storage 303. The controller 301 includes a job queue and can sequentially process the jobs queued (inserted) in the job queue. The job queue is a job execution queue and holds jobs in a list structure of First In First Out (FIFO). The queuing can be performed based on a job and job queue request received from the control apparatus 203 via the communication network 201 and communication device 302. The operator may create and queue jobs using the operation units 305 and display 306. Especially in the embodiment of the present invention, the jobs can include not only an exposure job but also an update job (to be described later).

The controller 301 can instruct the exposure device 307 to perform an exposure process based on the contents of an exposure job. Similarly, the controller 301 can retrieve an update image from the storage 303 and execute an installer program included in the update image based on the contents of an update job. The update image can be acquired via the communication network 201 and communication device 302 and stored in the storage 303. The update image can also be acquired by reading a medium including the update image using the media reading unit 304. Especially in the embodiment of the present invention, the job queue status includes a first status in which a new job is queued into a job queue and a second status in which no new job is queued into the job queue. The job queue can enter the second status (blocking status) in which queuing of a new job is prohibited, and can enter the first status upon canceling the blocking status. Moreover, pieces of information such as the job queue status, the status of a job in progress, and the result of the completed job can be displayed on the display 306. These pieces of information can be sent to the control apparatus 203 via the communication device 302 and communication network 201.

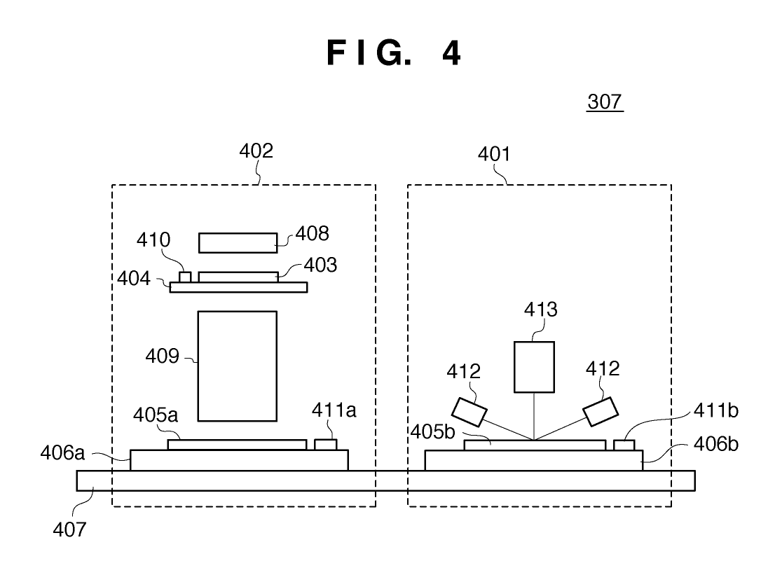

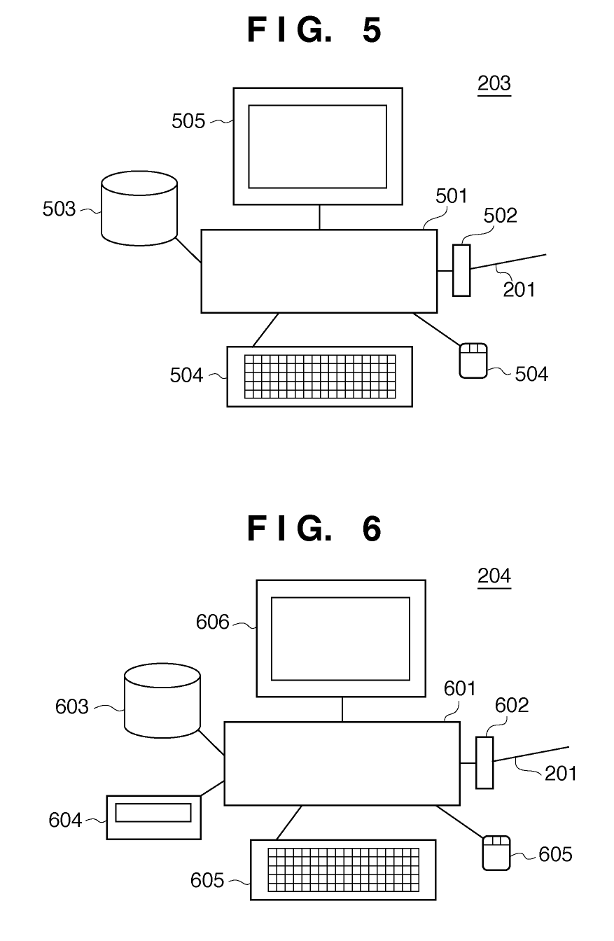

An exposure device of a semiconductor exposure apparatus including two wafer stages which hold wafers will be explained next as one example of the exposure device 307 which performs an exposure process. FIG. 4 is a view showing the arrangement of the exposure device 307. The exposure device 307 includes a measurement station 401 and exposure station 402.

The exposure station 402 includes a reticle stage 404 that supports a reticle 403. The exposure station 402 also includes two wafer stages 406, that is, 406a and 406b which support wafers 405, that is, 405a and 405b and can move between the two stations, and a base plate 407 which supports the two wafer stages 406. The exposure station 402 moreover includes an illumination optical system 408 which illuminates the reticle 403 supported by the reticle stage 404 with exposure light, and a projection optical system 409 which projects and transfers by exposure the pattern of the reticle 403 onto the wafer 405 on the wafer stage 406.

Although the exposure device 307 in this embodiment includes the two wafer stages 406, it may include one or three or more wafer stages 406. A case in which the exposure device 307 used is a scanning exposure device (scanner) that transfers by exposure a pattern formed on the reticle 403 onto the wafer 405 while moving (scanning) the reticle 403 and wafer 405 in synchronism with each other in a predetermined direction will be exemplified herein. The exposure device 307 may be a full-field transfer type exposure device (stepper), as a matter of course.

In the following description, a direction which matches that of the optical axis of the projection optical system 409 is defined as the Z-axis direction, the direction (scanning direction) to move the reticle 403 and wafer 405 in synchronism with each other on a plane perpendicular to the Z-axis direction is defined as the Y-axis direction, and a direction (non-scanning direction) perpendicular to both the Z- and Y-axis directions is defined as the X-axis direction. Also, the rotation directions about the X-, Y-, and Z-axes are defined as the θX, θY, and θZ directions, respectively.

A predetermined illumination region on the reticle 403 is illuminated with exposure light having a uniform distribution by the illumination optical system 408. Although the exposure light emitted by the illumination optical system 408 is generally light of a mercury lamp, KrF excimer laser, ArF excimer laser, F₂ laser, or EUV (Extreme Ultra Violet) light source, it may be another exposure light.

The reticle stage 404 supports the reticle 403. The reticle stage 404 can two-dimensionally move on a plane perpendicular to the optical axis of the projection optical system 409, that is, on the X-Y plane, and can finely rotate in the θZ direction. A reticle stage driving device (not shown) such as a linear motor drives the reticle stage 404 and can be controlled by the controller 301 shown in FIG. 3. A mirror is mounted on the reticle stage 404. A laser interferometer (not shown) is set at a position opposite to the mirror. The laser interferometer measures a rotation angle θZ and the position, in the two-dimensional direction on the X-Y plane, of the reticle 403 on the reticle stage 404 in real time, and outputs the measurement results to the controller 301. The controller 301 can position the reticle 403, supported by the reticle stage 404, by driving the reticle stage driving device based on the measurement results obtained by the laser interferometer.

The projection optical system 409 projects and transfers by exposure a pattern formed on the reticle 403 onto the wafer 405 at a predetermined projection magnification 13, and includes a plurality of optical elements, which are supported by a lens barrel serving as a metal member. In this embodiment, the projection optical system 409 is a reduction projection system with a projection magnification β of, for example, ¼ or ⅕.

Each wafer stage 406 supports the wafer 405, and includes a Z stage that holds the wafer 405 via a wafer chuck, an X-Y stage that supports the Z stage, and a base that supports the X-Y stage. A wafer stage driving device (not shown) such as a linear motor drives the wafer stage 406 and can be controlled by the controller 301.

A mirror that moves together with the wafer stage 406 is mounted on the wafer stage 406. A laser interferometer (not shown) is set at a position opposite to the mirror. The laser interferometer measures a rotation angle θZ and the position, in the two-dimensional direction on the X-Y plane, of the wafer stage 406 in real time, and outputs the measurement results to the controller 301. Similarly, the laser interferometer measures rotation angles θX and θY and the position, in the Z direction, of the wafer stage 406 in real time, and outputs the measurement results to the controller 301. The controller 301 can adjust the position of the wafer 405 in the X, Y, and Z directions by driving the X-Y stage and Z stage via the wafer stage driving device based on the measurement results obtained by the laser interferometer. This makes it possible to position the wafer 405 supported by the wafer stage 406.

The reticle stage 404 includes a reticle reference mark 410 formed on it, and the wafer stages 406 include stage reference marks 411, that is, 411a and 411b formed on them. A reticle alignment detection system (not shown) that detects the stage reference mark 411 via the reticle reference mark 410 and projection optical system 409 is set near the reticle stage 404. The use of the reticle alignment detection system allows alignment of the stage reference mark 411 with respect to the reticle reference mark 410.

The measurement station 401 includes a focus detection system 412 that detects the surface position information (the position information in the Z-axis direction and the tilt information) of the wafer 405, and a wafer alignment detection system 413 that detects the positions of the wafer 405 and stage reference mark 411.

The focus detection system 412 includes a light-projecting system which projects detection light onto the surface of the wafer 405, and a light-receiving system that receives the light reflected by the wafer 405. The detection results (measurement values) obtained by the focus detection system 412 are output to the controller 301. The controller 301 can adjust the tilt angle and the position (focus position), in the Z-axis direction, of the wafer 405, held by the Z stage, by driving the Z stage based on the detection result obtained by the focus detection system 412.

Also, the position detection results (measurement values) of the wafer 405 and stage reference mark 411 obtained by the wafer alignment detection system 413 are output to the controller 301 as alignment position information within a coordinate system defined by the laser interferometer. The stage reference mark 411 is located nearly flush with the surface of the wafer 405, and used to detect the reticle and wafer positions by the reticle alignment detection system and the wafer alignment detection system 413. Also, the stage reference mark 411 has a nearly flat surface portion and serves as the reference surface of the focus detection system 412. Stage reference marks 411 may be located at a plurality of corners of the wafer stage 406.

The wafer 405 includes a plurality of wafer alignment marks detected by the wafer alignment detection system 413. The plurality of wafer alignment marks are formed in the peripheries of respective shot regions on the wafer 405, and the positional relationships (in the X and Y directions) of the wafer alignment marks and the shot regions are assumed to be known. The exposure device 307 including two such wafer stages can, for example, load a second wafer 405 into the measurement station 401 and perform a measurement process for the second wafer 405 in the measurement station 401 during an exposure process for a first wafer 405 in the exposure station 402. After the respective processes are completed, the wafer stage 406 and first wafer 405 in the exposure station 402 move to the measurement station 401, and the wafer stage 406 and second wafer 405 in the measurement station 401 move to the exposure station 402 in parallel. After that, an exposure process for the wafer 405 is performed.

An exposure method in this embodiment will be explained next. After a wafer 405 is loaded into the measurement station 401, the stage reference mark 411 is detected by the wafer alignment detection system 413. To do this, the controller 301 moves the wafer stage 406 while monitoring the output from the laser interferometer so that the optical axis of the wafer alignment detection system 413 runs through the stage reference mark 411. With this operation, the wafer alignment detection system 413 measures the position information of the stage reference mark 411 within a coordinate system defined by the laser interferometer. Similarly, the focus detection system 412 detects the surface position information of the stage reference mark 411 in the measurement station 401.

The positions of respective shot regions on the wafer 405 are detected. The controller 301 moves the wafer stage 406 while monitoring the output from the laser interferometer so that the optical axis of the wafer alignment detection system 413 runs through the wafer alignment marks in the peripheries of respective shot regions on the wafer 405. In the process of the movement, the wafer alignment detection system 413 detects the plurality of wafer alignment marks formed in the peripheries of respective shot regions on the wafer 405. With this operation, the position of each wafer alignment mark within a coordinate system defined by the laser interferometer is detected. The positional relationships between the stage reference mark 411 and the respective wafer alignment marks are obtained based on the detection results of the stage reference mark 411 and the respective wafer alignment marks obtained by the wafer alignment detection system 413. Since the positional relationships between the respective wafer alignment marks and the respective shot regions are known, those between the stage reference mark 411 and the respective shot regions on the wafer 405 within the X-Y plane are, in turn, determined.

The focus detection system 412 detects the pieces of surface position information of the wafer 405 for all shot regions on the wafer 405. The detection results are stored in the controller 301 in correspondence with the position in the X and Y directions within a coordinate system defined by the laser interferometer. The positional relationships between the surface of the stage reference mark 411 and the surface of the wafer 405 in respective shot regions on it are determined based on the detection results of the surface position information of the stage reference mark 411 and the pieces of surface position information of the wafer 405 in all shot regions on it, which are obtained by the focus detection system 412.

Based on the results of the measurement process for the wafer 405 in the measurement station 401, the wafer 405 is exposed in the exposure station 402. The controller 301 moves the wafer stage 406 so as to detect the stage reference mark 411 using the reticle alignment detection system.

The reticle alignment detection system detects the stage reference mark 411 via the reticle reference mark 410 and projection optical system 409. That is, the positional relationships between the reticle reference mark 410 and the stage reference mark 411 in the X and Y directions and in the Z direction are detected via the projection optical system 409. With this operation, the position of a reticle pattern image projected onto the wafer 405 by the projection optical system 409 is detected using the stage reference mark 411 via the projection optical system 409.

After the position detection of a reticle pattern image formed by the projection optical system 409 is completed, the controller 301 moves the wafer stage 406 so that each shot region on the wafer 405 is positioned immediately below the projection optical system 409 in order to expose the shot regions on the wafer 405. The controller 301 scan-exposes each shot region on the wafer 405 using each measurement result obtained in the measurement station 401. During the scanning exposure, the controller 301 aligns each shot region on the wafer 405 with the reticle 403. This alignment is performed based on the positional relationships between the stage reference mark 411 and the respective shot regions, which are obtained in the measurement station 401, and the relationship between the position of the stage reference mark 411 and the position where the reticle pattern image is projected, which is obtained in the exposure station 402. Also during the scanning exposure, the positional relationship between the surface of the wafer 405 and the plane onto which the reticle pattern image is projected by the projection optical system 409 is adjusted. This adjustment is performed based on the positional relationship between the surface of the stage reference mark 411 and the plane on which the reticle pattern image is formed by the projection optical system 409, which is obtained in the measurement station 401.

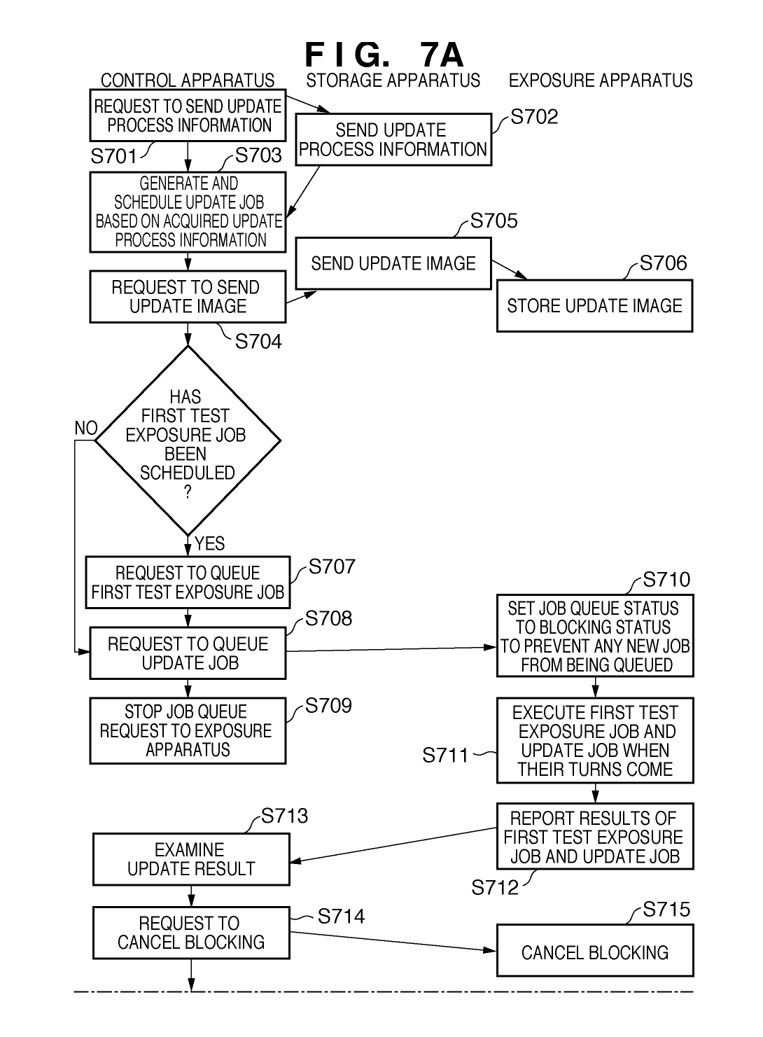

Details of the control apparatus 203 that controls the manufacturing process will be described next. FIG. 5 is a block diagram illustrating an example of the configuration of the control apparatus 203. The control apparatus 203 includes a controller 501, a communication device 502, a storage 503, one or more operation units 504, and a display 505. As an example, a known computer or board computer can implement the controller 501, and a known communication board compatible with the communication network 201 can implement the communication device 502. Also, as an example, a known hard disk can implement the storage 503, a known keyboard and mouse can implement the operation units 504, and a known display can implement the display 505.

The operator can create an exposure job and an exposure job schedule that are based on the manufacturing process using the operation units 504 and display 505. The control apparatus 203 can store the created exposure job and exposure job schedule in the storage 503. The control apparatus 203 can request the exposure apparatus 202 to queue the created exposure job into a job queue via the communication device 502 and communication network 201. The control apparatus 203 can acquire the result of the exposure job, executed by the exposure apparatus 202, via the communication network 201 and communication device 502. The control apparatus 203 can store the result of the acquired exposure job in the storage 503.

Especially in the embodiment of the present invention, the operator can generate and store an update job for updating the control software on the exposure apparatus 202, as in an exposure job. The update job includes pieces of information such as the update image name and version for specifying an update image. The control apparatus 203 can send the generated update job to the exposure apparatus 202 via the communication device 502 and communication network 201 and request the exposure apparatus 202 to queue the update job into a job queue. The control apparatus 203 can receive the result of the update process of the exposure apparatus 202 via the communication network 201 and communication device 502, and store the received result of the update process in the storage 503. The control apparatus 203 can also request, via the communication device 502 and communication network 201, the storage apparatus 204 that stores update software information to send the update image to the exposure apparatus 202.

Details of the storage apparatus 204 that stores information necessary for an update process for control software will be described next. FIG. 6 is a block diagram illustrating an example of the configuration of the storage apparatus 204. The storage apparatus 204 includes a controller 601, a communication device 602, a storage 603, a media reading unit 604, one or more operation units 605, and a display 606. As an example, the controller 601 can be implemented by a known computer or board computer, and the communication device 602 can be implemented by a known communication board compatible with the communication network 201. Also, as an example, the storage 603 can be implemented by a known hard disk, the media reading unit 604 can be implemented by a known reading device for an optical/magnetic disk or a magnetic tape, the operation units 605 can be implemented by a known keyboard and mouse, and the display 606 can be implemented by a known display.

The media reading unit 604 can read a medium including an update image provided by the manufacturing vendor of a semiconductor exposure apparatus, and the storage apparatus 204 can store the read update image in the storage 603. The storage apparatus 204 may acquire an update image via the communication network 201 and communication device 602. The storage apparatus 204 can send the update image to the exposure apparatus 202 via the communication device 602 and communication network 201 based on an update image send request from the control apparatus 203. The control apparatus 203 can generate and issue an update image send request to the storage apparatus 204, as described previously. The operator may create an update image send request using the operation units 605 and display 606 in the storage apparatus 204. The operator can also create update software information using the operation units 605 and display 606. The update software information includes at least the version information of update software and the position information of the update image in the storage 603 corresponding to the version. The storage apparatus 204 can store the created update software information in the storage 603. The storage apparatus 204 can display the update software information on the display 606 or deliver it via the communication device 602 and communication network 201 based on a given request.

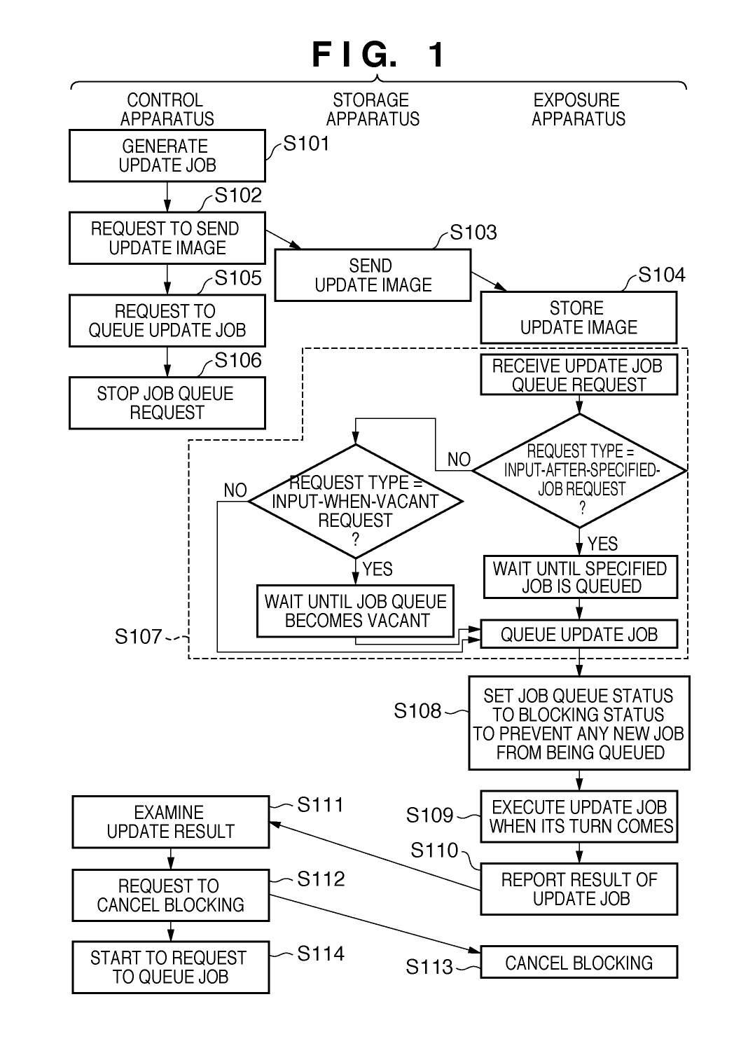

A method of updating control software on an exposure apparatus by the above-mentioned system for updating control software on an exposure apparatus will be described next. FIG. 1 is a flowchart illustrating one example of an update method to which the present invention is applied.

First, the control apparatus 203 generates an update job (S101). The control apparatus 203 issues, to the storage apparatus 204, a request to send an update image to the exposure apparatus 202 (S102). The issued request includes the version information of update software and information concerning the exposure apparatus as the delivery destination. In response to the issued request, the storage apparatus 204 inquires the update software information stored in its storage 603 and sends an update image corresponding to the requested version to the exposure apparatus 202 (S103). Upon receiving the update image, the exposure apparatus 202 stores the update image at an appropriate location in its storage 303 (S104). The process of acquiring the update image need only be performed before the control software is actually updated (i.e., before the turn of the queued update job comes), and need not always be performed at the timing shown in FIG. 1. As a matter of course, the update image need not always be transferred via the communication network 201, either, and a medium including the update image may be read and acquired by the exposure apparatus 202, as in the prior art.

The control apparatus 203 requests the exposure apparatus 202 to queue the update job into a job queue (S105).

This queue request is characterized by being classified into at least three types to be described hereinafter. A queue request of the first type is a request to immediately queue the update job. This request type will be referred to as an “immediate-input request” hereinafter. A queue request of the second type is a request to queue the update job immediately after a specified exposure job is queued. This request type will be referred to as an “input-after-specified-job request” hereinafter. A queue request of the third type is a request to queue the update job in a vacant time (i.e., when no more job is present in the job queue). This request type will be referred to as an “input-when-vacant request” hereinafter.

After issuing an update job queue request to the exposure apparatus 202, the control apparatus 203 immediately stops requesting the exposure apparatus 202 for job queuing (S106).

In response to the update job queue request, the exposure apparatus 202 queues the update job in accordance with the request type adopted (S107). That is, if the request type is an immediate-input request, the exposure apparatus 202 immediately queues the update job. If the request type is an input-after-specified-job request, the exposure apparatus 202 suspends update job queuing until a specified job is queued. If the request type is an input-when-vacant request, the exposure apparatus 202 suspends update job queuing until the job queue becomes vacant.

After completing the update job queuing, the exposure apparatus 202 sets the job queue status to the blocking status (second status) to prevent any new job from being queued (S108). After that, when the turn of the queued update job comes, the exposure apparatus 202 performs an update process (S109). The update process is realized by executing an installer program included in the update image. The update process includes the stop of control software, the replacement of an update file, the backing up of a file before updating, the takeover of various types of parameters, the deletion of any unnecessary files (rename process), and the startup of the updated control software. After completing the update process, the exposure apparatus 202 sends a report on the result of the update process to the control apparatus 203 (S110).

The operator determines in the control apparatus 203 whether the received result of the update process is successful (S111). If the operator determines that the update process has succeeded, he or she requests, via the control apparatus 203, the exposure apparatus 202 to change the job queue status to the first status in which blocking is canceled (S112). In response to the request, the exposure apparatus 202 cancels the job queue blocking (S113). In contrast, if the operator determines that the update process has failed, he or she or the manufacturing vendor of the exposure apparatus needs to examine the cause of the failure and restore the data damaged by the failure or to perform a process for returning the control software on the exposure apparatus to the one before updating (not shown). A mechanism which automatically performs, the examination of the result of the update process and the blocking cancel requesting, based on the result of the update process may be adopted. Lastly, the control apparatus 203 starts to request the exposure apparatus 202 to queue a new job, and a series of steps of the update process for the control software on the exposure apparatus is completed (S114).

All or some of the generation of an update job (S101), the update image send requesting (S102), and the update job queue requesting (S105) may be performed in the exposure apparatus 202 instead of the control apparatus 203, unlike the foregoing description. Similarly, one or both of the examination of the update result (S111) and the blocking cancel requesting (S112) may be performed in the exposure apparatus 202 instead of the control apparatus 203. This applies to a case in which a system configuration includes neither the control apparatus 203 nor the communication network 201, or in which the control apparatus 203 is temporarily unavailable because of a breakdown, maintenance, or various kinds of factors.

As described above, a system and method for updating control software on an exposure apparatus to which the present invention is applied can schedule jobs so as to minimize the period for which an exposure process is stopped for updating and to automatically perform the updating.

### Second Embodiment

The second embodiment of an exposure apparatus and semiconductor manufacturing system to which the present invention is applied will be explained.

FIGS. 2 to 6 show details of the system configuration and components in this embodiment, as in the above-described first embodiment. Details of the drawings are the same as in the first embodiment, so a description thereof will not be given but noteworthy features in the second embodiment will be described below.

In addition to the pieces of information mentioned in the first embodiment, update software information generated and stored in a storage apparatus 204 includes at least the following two pieces of information: information (first information) concerning a first test exposure process to be performed before an update process and a second test exposure process to be performed after the update process; and information (second information) concerning the time expected to be taken for the update process. The first information on the necessity of the test exposure and the second information on the expected update process time are determined based on the past successful records of the update process.

A control apparatus 203 can acquire the update software information via a communication network 201 from the storage apparatus 204, refer to this information, and create an update job schedule using the update software information. That is, it is possible to determine the timing, at which an update job is queued into a job queue, by taking into consideration the expected update process time and the vacant time of an exposure apparatus 202, and to queue first and second test exposure jobs to be performed before and after the update job by taking into consideration the necessity of these, first and second test exposure processes.

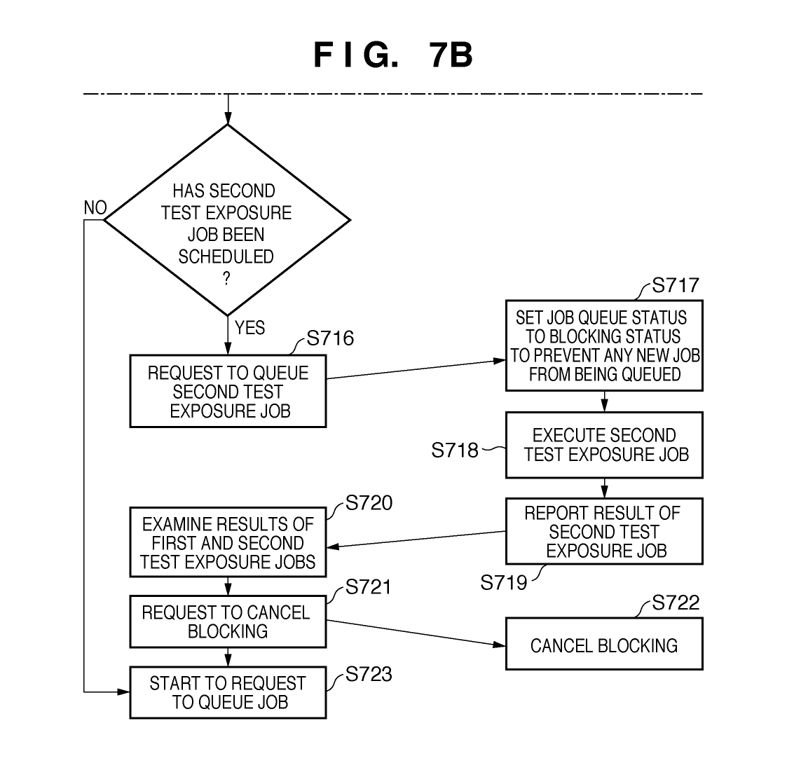

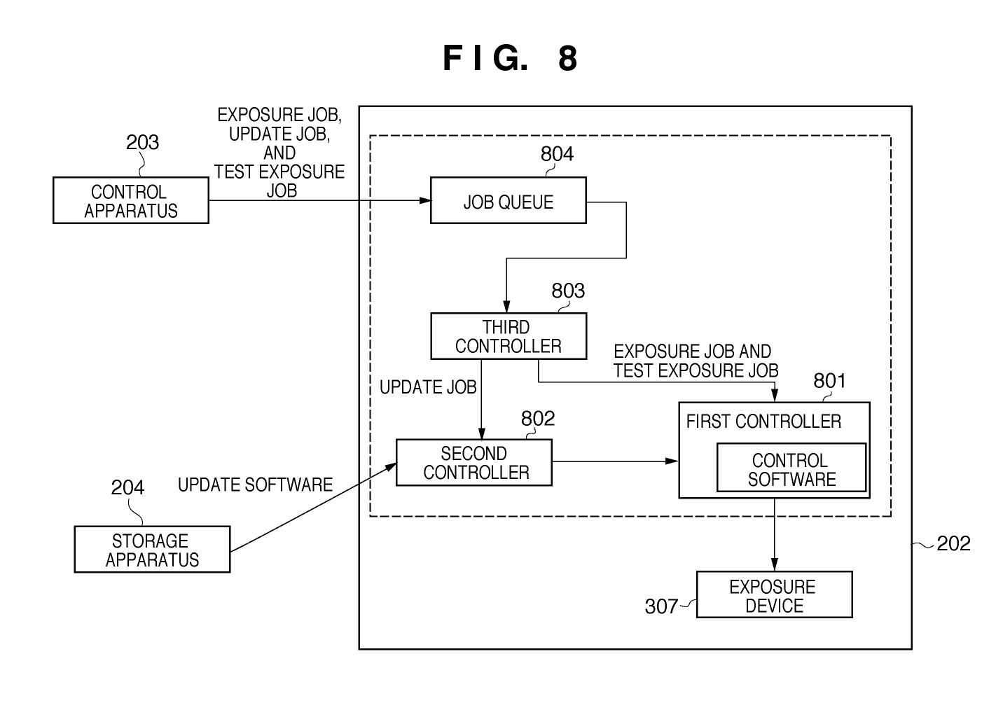

A method of updating control software by the above-mentioned system for updating control software on an exposure apparatus will be described next. FIGS. 7A and 7B are flowcharts illustrating one example of an update method to which the present invention is applied.

First, the control apparatus 203 requests the storage apparatus 204 to send update software information (S701). In response the request, the storage apparatus 204 sends update software information to the control apparatus 203 (S702). The control apparatus 203 generates and schedules an update job based on the acquired update software information (S703).

The update job scheduling can include the following two determination operations. First, the timing at which an update job is queued into the exposure apparatus is determined by taking into consideration the expected update process time and the vacant time of a semiconductor exposure apparatus, which are included in the update software information. Second, the timing at which an update job is queued into the exposure apparatus is determined by designating an exposure job desired to be executed before updating.

The control apparatus 203 issues, to the storage apparatus 204, an update image send request to the exposure apparatus (S704). The send request includes information concerning the version information of control software to be updated to, and information concerning the exposure apparatus as the destination where the update image is to be located. In response to the send request, the storage apparatus 204 inquires the update software information stored in its storage 603 and sends an update image corresponding to the requested version to the exposure apparatus 202 (S705). Upon receiving the update image, the exposure apparatus 202 stores the update image at an appropriate location in its storage 303 (S706). The process of acquiring the update image need only be performed before the control software is actually updated (i.e., before the turn of the queued update job comes), and need not always be performed at the timing shown in FIGS. 7A and 7B. As a matter of course, the update image need not always be transferred via the communication network 201, either, and a medium including the update image may be read and acquired by the exposure apparatus 202, as in the prior art.

The control apparatus 203 requests the exposure apparatus 202 to queue the update job into a job queue (S708). If first and second test exposure jobs are prepared (scheduled) by the update software information, the control apparatus 203 generates a first test exposure job and a second test exposure job and requests the exposure apparatus 202 to queue the first test exposure job immediately before the update job (S707). After requesting the exposure apparatus 202 to queue the first test exposure job and the update job, the control apparatus 203 immediately stops requesting the exposure apparatus 202 for job queuing (S709). The exposure apparatus 202 queues the first test exposure job and the update job into a job queue in the order in which they are requested to be queued.

After completing the queuing of the first test exposure job and update job, the exposure apparatus 202 immediately sets the job queue status to the blocking status to prevent any new job from being queued (S710). After that, when the turns of the queued first test exposure job and update job come, the exposure apparatus 202 sequentially performs a first test exposure process and an update process (S711). The update process includes the stop of control software, the replacement of an update file, the backing up of a file before updating, the takeover of various types of parameters, the deletion of any unnecessary files (rename process), and the startup of the updated control software.

After completing the first test exposure process and the update process, the exposure apparatus 202 sends reports on the results of the first test exposure process and update process to the control apparatus 203 (S712). The operator performs first determination in the control apparatus 203 based on the received result of the update process (S713).

If the operator determines in step S713 that the update process has succeeded, he or she requests the exposure apparatus 202 to cancel the job queue blocking via the control apparatus 203 (S714). In response to the request, the exposure apparatus 202 cancels the job queue blocking (S715).

If a second test exposure process after the update process is not scheduled, the control apparatus 203 starts to request the exposure apparatus 202 to queue a new job, and a series of steps of the update process for the control software on the exposure apparatus is completed (S723).

If a second test exposure process has been scheduled, the control apparatus 203 requests the exposure apparatus 202 to queue a second test exposure job (S716). After completing the queuing of the second test exposure job, the exposure apparatus 202 sets the job queue status to the blocking status again (S717). After that, the exposure apparatus 202 performs a second test exposure process (S718), and sends the process result to the control apparatus 203 (S719). The operator performs second determination in the control apparatus 203 based on the received results of the first test exposure process and second test exposure process (S720). If the operator determines in step S720 that the update process has succeeded, he or she issues a job queue blocking cancel request to the exposure apparatus 202 via the control apparatus 203 (S721). In response to the request, the exposure apparatus 202 cancels the job queue blocking (S722). Lastly, the control apparatus 203 starts to request the exposure apparatus 202 to queue a new job, and a series of steps of the update process for the control software is completed (S723).

Note that if the operator determines in the first determination (S713) or the second determination (S720) that the update process has failed, he or she or the manufacturing vendor of the exposure apparatus needs to examine the cause of the failure and restore the data damaged by the failure or to perform a process for returning the control software on the exposure apparatus to the one before updating (not shown).

The first determination (S713), the blocking cancel requesting (S714), the second determination (S720), and the blocking cancel requesting (S721) may be performed in the exposure apparatus 202. Alternatively, a mechanism which automatically performs, the first determination (S713), the blocking cancel requesting (S714), the second determination (S720), and the blocking cancel requesting (S721), based on the results of the update process and first and second test exposure processes may be adopted.

FIG. 8 shows the relationship among the control apparatus 203, the storage apparatus 204, and the exposure apparatus 202 in the first and second embodiments. A dotted frame in a solid frame indicating the exposure apparatus 202 in FIG. 8 indicates the controller 301, the storage 303, the media reading unit 304, the operation units 305, and the display 306 of the exposure apparatus 202.

Software portion of the exposure apparatus 202 includes a job queue 804, first controller 801, second controller 802, and third controller 803. An exposure job, an update job, and first and second test exposure jobs that are generated by the control apparatus 203 are queued into the job queue 804. The job queue status includes a first status in which a new job is queued into the job queue 804 and a second status in which no new job is queued into the job queue 804.

The third controller 803 controls the job queue 804 to determine the timing at which an update job is queued into the job queue 804. The timing at which an update job is queued is determined based on the time expected to be taken for an update process or selected in accordance with the queue request type adopted. The queue request type is, for example, the immediate-input request, input-after-specified-job request, or input-when-vacant request, described in the first embodiment. Also, the third controller 803 switches the job queue status between a first status in which queuing of a new job is enabled and a second status in which queuing of a new job is blocked.

The first controller 801 includes control software and controls the exposure process of the exposure device 307 based on the control software in accordance with an exposure job.

The second controller 802 controls an update process for the control software of the first controller 801 using update software sent from the storage apparatus 204.

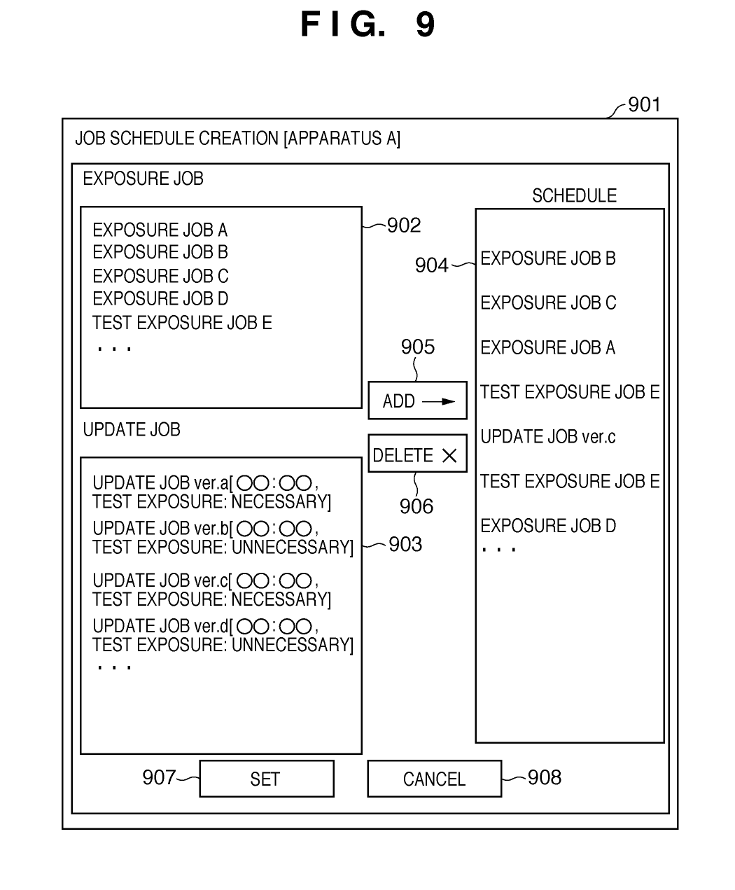

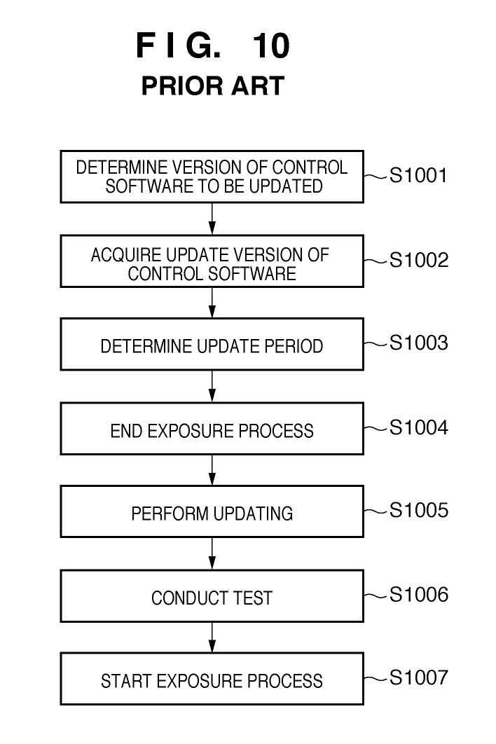

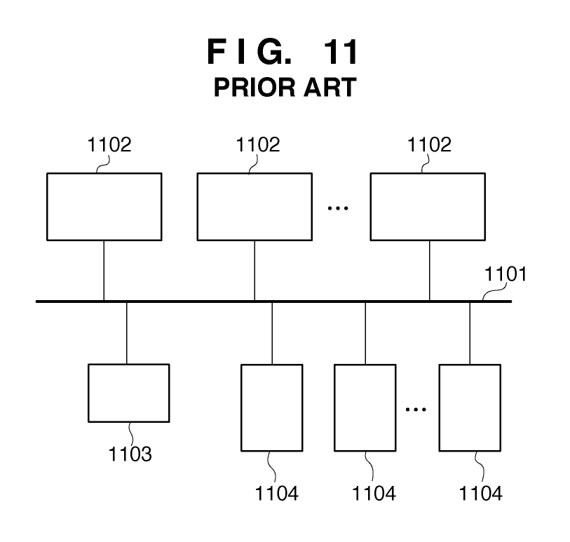

FIG. 9 illustrates an example of a display window for scheduling an update job in the control apparatus 203. This window is displayed on the display 505 in the control apparatus 203 and implements schedule creation by one or more operation units 504 in the control apparatus 203.

Reference numeral 901 denotes a field to display the name of an exposure apparatus for which a schedule is to be determined. Reference numeral 902 denotes a field to display the name of the created exposure job, and an exposure job corresponding to the exposure job name is stored in the storage 503 of the control apparatus 203. Reference numeral 903 denotes a field to display the name of the created update job, and an update job corresponding to the update job name is stored in the storage 503 of the control apparatus 203. The update job name display field 903 can display at least the version information of update software, the information of the expected update process time, and the information of the necessity of a test exposure process, and these pieces of information can be acquired by the storage apparatus 204 which stores update software information. Reference numeral 904 denotes a field to display a job schedule being created. An arbitrary job name described in the exposure job name display field 902 or update job name display field 903 can be added to the schedule display field 904 by pressing down an add button 905. Conversely, an arbitrary job described in the schedule display field 904 can be deleted by pressing down a delete button 906. After the schedule creation is completed, jobs corresponding to the job names can be queued into the exposure apparatus 202, for which a schedule is to be determined, in the order in which the jobs are described in the schedule display field 904, by pressing down a set button 907. Also, schedule creation can be canceled by pressing down a cancel button 908. Note that FIG. 9 illustrates one example given to help a better understanding of the present invention, and does not limit the scope of the present invention.

Division of an update process for control software will be described next. An installer program included in an update image in this embodiment may be configured to be able to perform an update process by dividing it into a plurality of steps. The division includes division into at least two steps: (1) a step which does not require stop of an exposure process being performed in accordance with control software before updating; and (2) a step which requires stop of an exposure process being performed in accordance with control software before updating. At this time, based on the division, an update job can be divided into a first update job which requires stop of an exposure process, and a second update job which does not require stop of an exposure process. The first update job and the second update job can be scheduled to be queued into the exposure apparatus 202 in different periods of time.

As has been described above, an exposure apparatus and semiconductor manufacturing system to which the present invention is applied can schedule jobs so as to minimize the period for which an exposure process is stopped for an update process and to automatically perform the updating. Also, a test exposure process can be scheduled to be automatically performed as well, together with the update process.

Although two embodiments have been described above, note that embodiments that can be practiced by arbitrarily combining the features individually described in the respective embodiments fall within the scope of embodiments of the present invention.

### Embodiment of Method of Manufacturing Device

An example of a method of manufacturing a device using the above-mentioned exposure apparatus will be explained next. The device is manufactured by a step of exposing a substrate coated with a photosensitive agent using the exposure apparatus in one of the above-described first and second embodiments, a step of developing the substrate exposed in the exposing step, and subsequent known steps. The device can be, for example, a semiconductor integrated circuit device or a liquid crystal display device. The substrate can be, for example, a wafer or a glass plate. The subsequent known steps include, for example, oxidation, film formation, vapor deposition, doping, planarization, etching, resist removal, dicing, bonding, and packaging steps.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-103359, filed Apr. 21, 2009, which is hereby incorporated by reference herein in its entirety.

What is claimed is:

1. An exposure apparatus comprising:
an exposure device configured to perform an exposure process for a substrate; and
a controller configured to control an operation of the exposure device in accordance with control software and perform an update process for the control software,
wherein the controller is configured to
queue an exposure job corresponding to the exposure process and an update job corresponding to the update process; and
causes the exposure device to perform an exposure process corresponding to the queued exposure job if the queued exposure job is output, and perform an update process corresponding to the queued update job if the queued update job is output.

2. The apparatus according to claim 1, wherein
the update job includes a first update job which requires stop of an exposure process being performed in accordance with control software before updating, and a second update job which does not require stop of an exposure process being performed in accordance with control software before updating, and
the controller is configured to perform an update process in accordance with the queued second update job in parallel with an exposure process of the exposure device if the queued second update job is output.

3. The apparatus according to claim 1, wherein
the controller is configured, if the update job is queued, to stop queuing of a new job and to perform an update process in accordance with the queued update job, and then, if the performed update process is determined to have succeeded, to enable queuing of a new job.

4. The apparatus according to claim 1, wherein
the controller is configured to select a timing, at which an update job for which a queue request has been issued is queued, in accordance with a type of the queue request, and
the timing includes a timing immediately after the queue request is issued to the controller, a timing immediately after a specified exposure job is queued, and a timing immediately after all queued jobs are output.

5. The apparatus according to claim 1, wherein the controller is configured to determine a timing, at which an update job is queued, based on a time expected to be taken for an update process performed in accordance with the update job.

6. The apparatus according to claim 3, wherein the controller is configured, if a first test exposure job associated with a first test exposure process to be performed before an update process and a second test exposure job associated with a second test exposure process to be performed after the update process are prepared, to queue the first test exposure job before queuing of an update job associated with the update process and to queue the second test exposure job after the queuing of the update job so that the first test exposure process, the update process, and the second test exposure process are sequentially performed in accordance with the queued first test exposure job, the queued update job, and the queued second test exposure job, respectively, and then, if the update process is determined to have succeeded based on the results of the performed first and second test exposure processes, to enable queuing of a new job.

7. A device manufacturing system comprising:
an exposure apparatus defined in claim 1; and
a control apparatus configured to generate the exposure job and the update job.

8. A method of manufacturing a device, the method comprising:
exposing a substrate using an exposure apparatus;
developing the exposed substrate; and
processing the developed substrate to manufacture the device,
wherein the exposure apparatus comprises:
an exposure device configured to perform an exposure process for a substrate; and
a controller configured to control an operation of the exposure device in accordance with control software and perform an update process for the control software, and
wherein the controller is configured to
queue an exposure job corresponding to the exposure process and an update job corresponding to the update process; and
causes the exposure device to perform an exposure process corresponding to the queued exposure job if the queued exposure job is output, and perform an update process corresponding to the queued update job if the queued update job is output.
